(19) United States
(12) Patent Application Publication
(10) Pub. No.: US 2025/0015147 A1
(43) Pub. Date: Jan. 9, 2025

(54) SEMICONDUCTOR DEVICE AND METHOD OF MANUFACTURING THE SAME

(71) Applicant: Renesas Electronics Corporation, Tokyo (JP)

(72) Inventors: Yuto OMIZU, Tokyo (JP); Yu NAGAHAMA, Tokyo (JP)

(21) Appl. No.: 18/762,960

(22) Filed: Jul. 3, 2024

(30) Foreign Application Priority Data
Jul. 7, 2023 (JP) 2023-112582

(51) Int. Cl. H01L 29/40; H01L 29/423; H01L 29/66; H01L 29/78

(52) U.S. Cl. CPC H01L 29/407; H01L 29/4236; H01L 29/66734; H01L 29/7813

(57) ABSTRACT

A field plate electrode FP is formed inside the trench TR via an insulating film IF1. The insulating film IF1 is retracted so that the position of the upper surface of the insulating film IF1 is lower than the position of the upper surface of the field plate electrode FP. An embedded insulating film EF1 is formed to cover the field plate electrode FP and the insulating film IF1. The embedded insulating film EF1 is retracted so that the position of the upper surface of the embedded insulating film EF1 is lower than the position of the upper surface of the field plate electrode FP. A gate insulating film GI is formed inside the trench TR, and an insulating film IF2 is formed to cover the field plate electrode FP. A gate electrode is formed on the field plate electrode FP via the insulating film IF2.

### CROSS-REFERENCE TO RELATED APPLICATIONS

The disclosure of Japanese Patent Application No. 2023-112582 filed on Jul. 7, 2023, including the specification, drawings and abstract is incorporated herein by reference in its entirety.

### BACKGROUND

The present disclosure relates to a semiconductor device and a method of manufacturing the same, and more particularly, to a semiconductor device and a method of manufacturing the same including a gate electrode and a field plate electrode inside a trench.

In a semiconductor device including a semiconductor element such as a power MOSFET (Metal Oxide Semiconductor Field Effect Transistor), a trench gate structure in which a gate electrode is embedded in a trench is applied. One type of a trench gate structure is a split gate structure in which a field plate electrode is formed at a lower part of a trench and a gate electrode is formed at an upper part of the trench. A source potential is supplied from the source electrode to the field plate electrode. By expanding a depletion layer in a drift region by the field plate electrode, it is possible to increase the concentration of the drift region, and it is possible to reduce the resistance of the drift region.

For example, Patent Document 1 discloses a split-gate MOSFET. In Patent Document 1, a polycrystalline silicon film is formed inside the trench and on the semiconductor substrate, and an anisotropic etch process is performed on the polycrystalline silicon film to remove the polycrystalline silicon film outside the trench, thereby forming a field plate electrode inside the trench. Thereafter, an insulating film covering the field plate electrode is formed by a thermal oxidation method, and a gate electrode is formed on the insulating film.

There is a disclosed technique listed below.
[Patent Document 1] Japanese Unexamined Patent Application Publication No. 2011-199109

### SUMMARY

When the field plate electrode is formed, the upper corner of the field plate electrode tends to be processed into a protruding shape. Therefore, the electric field tends to concentrate at the protruded portion, and a leakage current tends to be generated between the gate electrode and the field plate electrode. In addition, even when an insulating film covering the field plate electrode is formed, the thickness of the insulating film may be locally reduced depending on the exposure state of the field plate electrode.

The main purpose of the present disclosure is to improve the reliability of a semiconductor device by securing the breakdown voltage between the gate electrode and the field plate electrode. Other objects and novel features will become apparent from the description of this specification and the accompanying drawings.

The typical ones of the embodiments disclosed in the present disclosure will be briefly described as follows.

A method of manufacturing a semiconductor device according to one embodiment comprises: (a) preparing a semiconductor substrate of a first conductivity type having an upper surface and a lower surface; (b) after (a), forming a trench in the semiconductor substrate so as to reach a predetermined depth from the upper surface of the semiconductor substrate to the lower surface of the semiconductor substrate; (c) after (b), forming a first insulating film inside the trench and on the upper surface of the semiconductor substrate; (d) after (c), forming a field plate electrode on the first insulating film inside the trench; (e) after (d), removing the first insulating film located on the upper surface of the semiconductor substrate and retreating the first insulating film inside the trench toward the bottom of the trench so that, in a cross-sectional view, the position of the upper surface of the first insulating film located inside the trench is lower than the position of the upper surface of the field plate electrode; (f) after (e), forming an embedded insulating film on the upper surface of the semiconductor substrate and inside the trench so as to cover the field plate electrode and the first insulating film; (g) after (f), removing the embedded insulating film located on the upper surface of the semiconductor substrate and retreating the embedded insulating film inside the trench toward the bottom of the trench so that, in a cross-sectional view, the position of the upper surface of the embedded insulating film located inside the trench is lower than the position of the upper surface of the field plate electrode; (h) after (g), forming a gate insulating film inside the trench located on the upper surface of the embedded insulating film by performing a dry oxidation treatment and forming a second insulating film so as to cover the field plate electrode exposed from the embedded insulating film by (g); and (i) after (h), forming a gate electrode on the field plate electrode via the second insulating film inside the trench.

A semiconductor device according to one embodiment comprises: a semiconductor substrate of a first conductivity type having an upper surface and a lower surface; a trench formed in the semiconductor substrate so as to reach a predetermined depth from the upper surface of the semiconductor substrate toward the lower surface of the semiconductor substrate; a field plate electrode formed inside the trench; a gate electrode formed above the field plate electrode inside the trench; and an insulating film formed inside the trench so as to be located between each of the semiconductor substrate, the field plate electrode, and the gate electrode. A corner of an upper portion of the field plate electrode is chamfered or rounded. A part of the gate electrode is formed also between the field plate electrode and the semiconductor substrate as an embedded portion. A thickness of the insulating film formed between the embedded portion and the field plate electrode is thickest between the deepest portion of the embedded portion and the field plate electrode.

According to one embodiment, the reliability of semiconductor device can be improved.

### BRIEF DESCRIPTION OF THE DRAWINGS

FIG. 1 is a plan view indicating a semiconductor device in a first embodiment.

FIG. 2 is a main portion plan view indicating a semiconductor device in the first embodiment.

FIG. 3 is a main portion plan view indicating a semiconductor device in the first embodiment.

FIG. 4 is a cross-sectional view indicating a semiconductor device in the first embodiment.

FIG. 5 is a main portion cross-sectional view indicating a semiconductor device in the first embodiment.

FIG. 6 is a main portion cross-sectional view indicating a semiconductor device in the first embodiment.

FIG. 7 is a cross-sectional view showing a manufacturing process of a semiconductor device in the first embodiment.

FIG. 8 is a cross-sectional view illustrating a manufacturing process following FIG. 7.

FIG. 9 is a cross-sectional view illustrating a manufacturing step following FIG. 8.

FIG. 10 is a cross-sectional view illustrating a manufacturing process following FIG. 9.

FIG. 11 is a cross-sectional view illustrating a manufacturing step following FIG. 10.

FIG. 12 is a cross-sectional view illustrating a manufacturing process following FIG. 11.

FIG. 13 is a cross-sectional view illustrating a manufacturing process following FIG. 12.

FIG. 14 is a cross-sectional view illustrating a manufacturing process following FIG. 13.

FIG. 15 is a cross-sectional view illustrating a manufacturing process following FIG. 14.

FIG. 16 is a cross-sectional view illustrating a manufacturing step following FIG. 15.

FIG. 17 is a cross-sectional view illustrating a manufacturing step following FIG. 16.

FIG. 18 is a cross-sectional view illustrating a manufacturing step following FIG. 17.

FIG. 19 is a cross-sectional view illustrating a manufacturing step following FIG. 18.

FIG. 20 is a cross-sectional view illustrating a manufacturing process following FIG. 19.

FIG. 21 is a cross-sectional view illustrating a manufacturing step following FIG. 20.

FIG. 22 is a cross-sectional view illustrating a manufacturing step following FIG. 21.

FIG. 23 is a cross-sectional view illustrating a manufacturing step following FIG. 22.

FIG. 24 is a main portion cross-sectional view showing a semiconductor device in the examined example 1.

FIG. 25 is a main portion cross-sectional view showing a semiconductor device in the examined example 1.

FIG. 26 is a main portion cross-sectional view showing a semiconductor device in the examined example 2.

FIG. 27 is a main portion cross-sectional view showing a semiconductor device in the examined example 3.

### DETAILED DESCRIPTION

Hereinafter, embodiments are described in detail with reference to the drawings. In all the drawings for explaining the embodiments, members having the same functions are denoted by the same reference numerals, and repetitive descriptions thereof are omitted. In the following embodiments, descriptions of the same or similar parts will not be repeated in principle except when particularly necessary.

In addition, the X direction, the Y direction, and the Z direction described in the present disclosure intersect each other and are orthogonal to each other. In the present disclosure, the Z direction is described as a vertical direction, a height direction, or a thickness direction of a certain structure. In addition, the expression “plan view” used in the present disclosure means that the plane formed by the X direction and the Y direction is a “plane” and the “plane” is viewed from the Z direction.

### First Embodiment

### <Structure of Semiconductor Device>

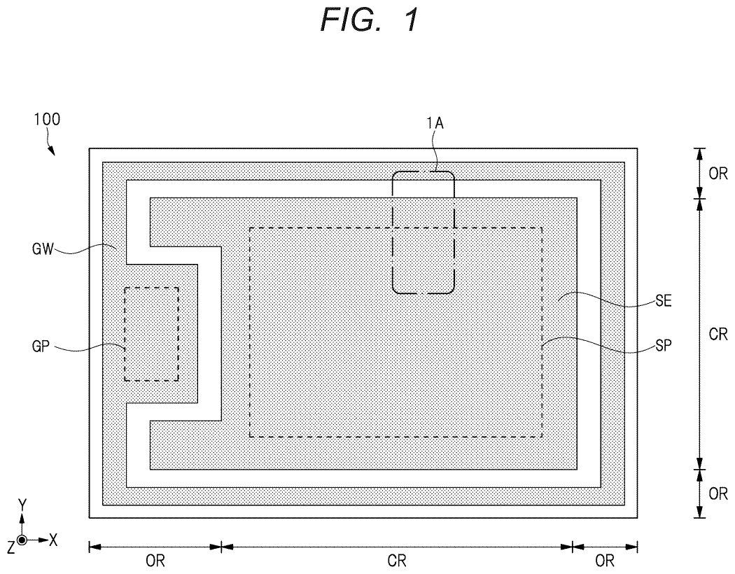

A semiconductor device 100 in a first embodiment will be described below with reference to FIGS. 1 to 6. The semiconductor device 100 includes a MOSFET of a trench gate structure as a semiconducting element. The MOSFET of the first embodiment has a split gate structure with a gate electrode GE and a field plate electrode FP.

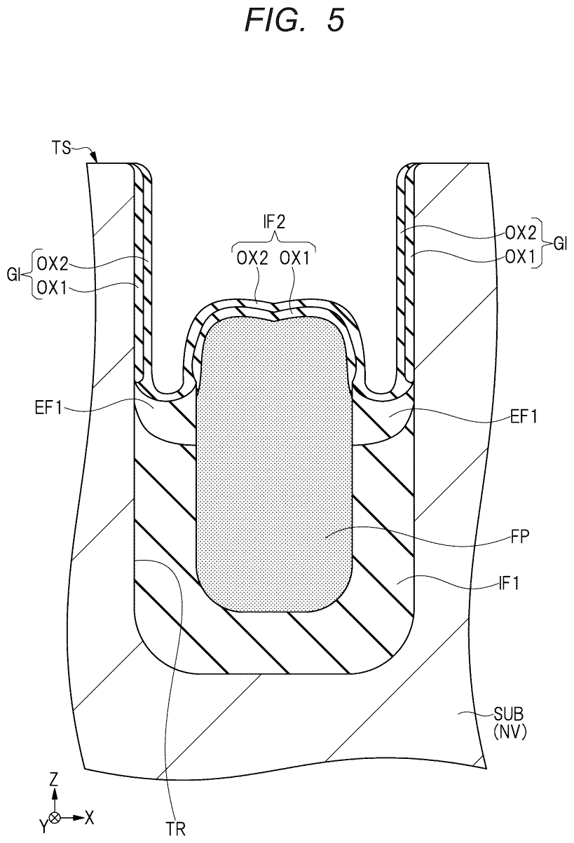

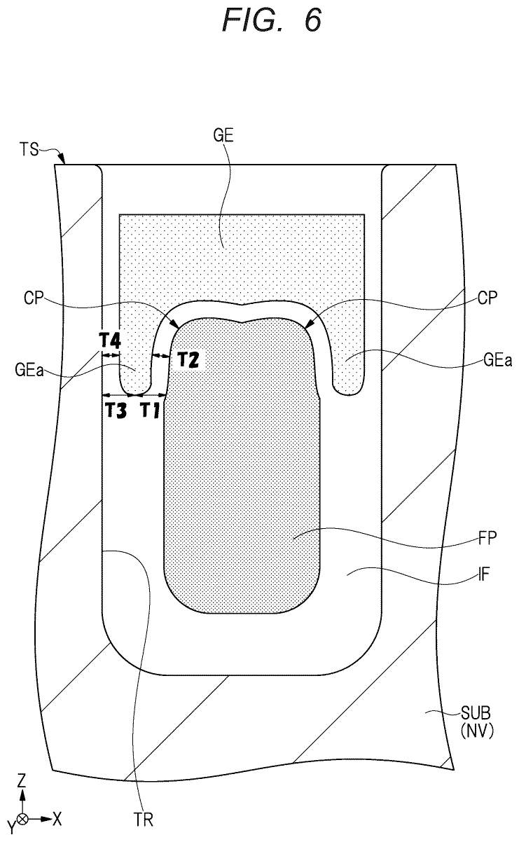

The main features of the present disclosure are the shape of the upper part of the field plate electrode FP, the shape of the embedded insulating film EF1, and the forming method of the insulating film IF2, and these features will be described in detail with reference to FIGS. 5 and 6 after the explanation of “structure of semiconductor device” and “manufacturing method of semiconductor device”.

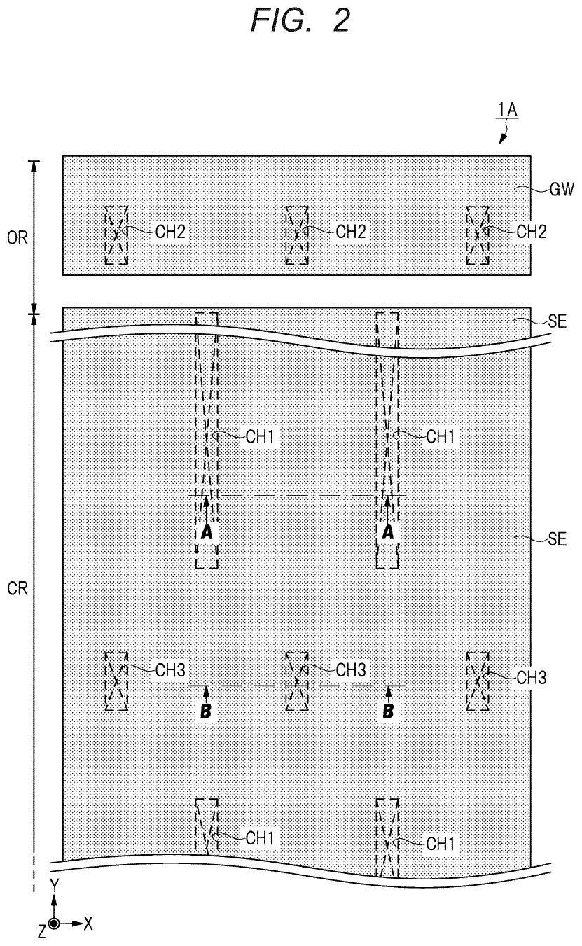

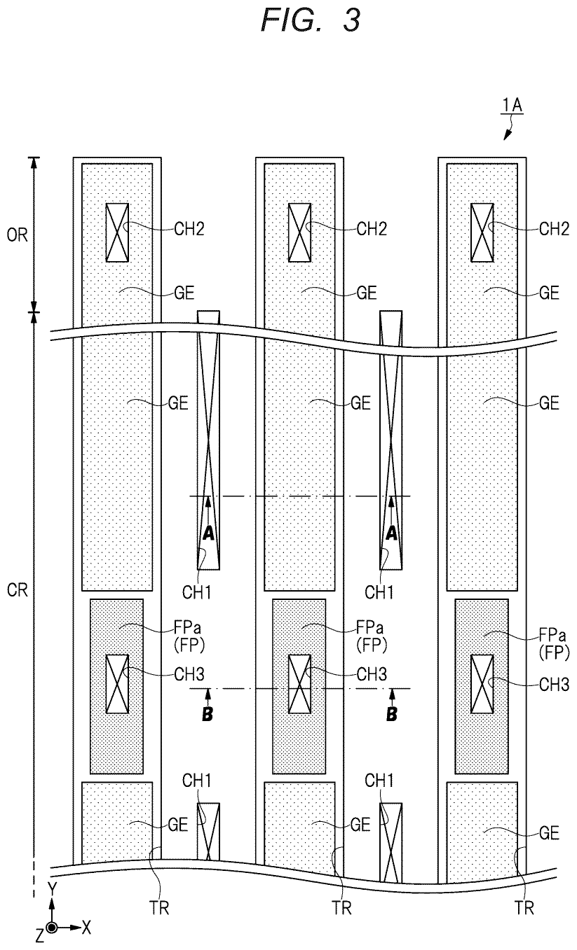

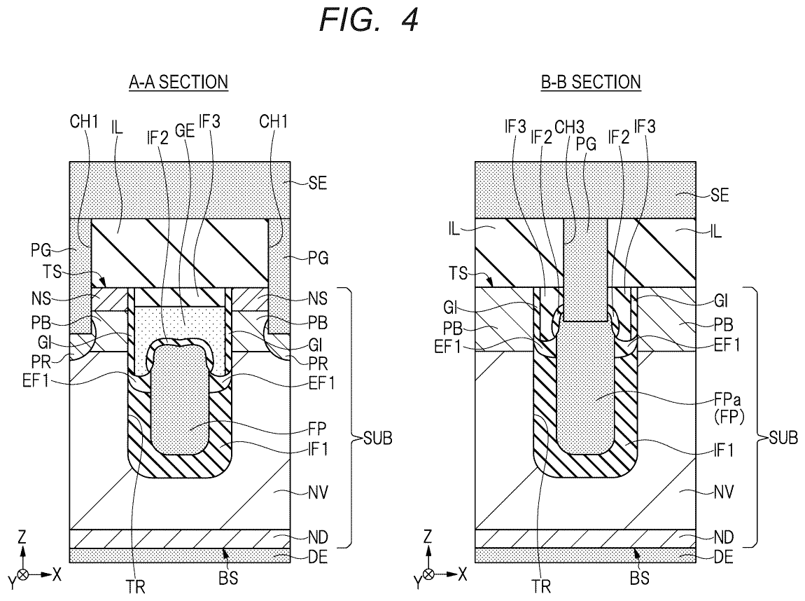

FIG. 1 is a plan view of a semiconductor chip as a semiconductor device 100. FIG. 2 and FIG. 3 are enlarged main portion plan views of the region 1A shown in FIG. 1. FIG. 3 shows the lower structure of FIG. 2, mainly showing the trench gate structure formed in the semiconductor substrate SUB. In addition, the positions of the holes CH1, CH2, CH3 indicated by the broken lines in FIG. 2 coincide with the positions of the holes CH1, CH2, CH3 shown in FIG. 3. FIG. 4 is a cross sectional view along A-A line and B-B lines shown in FIGS. 2 and 3.

FIG. 1 shows a wiring pattern formed mainly above the semiconductor substrate SUB. The semiconductor device 100 has a cell region CR and an outer peripheral region OR surrounding the cell region CR in a plan view. In the cell region CR, main semiconducting elements such as a plurality of MOSFETs are formed. The outer peripheral region OR is used for connecting the gate wiring GW to the gate electrode GE, functioning as a termination region, and the like.

As shown in FIGS. 1 and 2, most of the cell region CR is covered with a source electrode SE. In plan view, the gate wiring GW surrounds the source electrode SE. Although not illustrated here, the source electrode SE and the gate wiring GW are covered with a protective film such as a polyimide film. Openings are provided in portions of the protective film, and the source electrode SE and the gate wiring GW exposed in the openings become the source pad SP and the gate pad GP. External connecting members are connected to the source pad SP and the gate pad GP, so that the semiconductor device 100 is electrically connected to another semiconductor chip, a lead frame, a wiring substrate, or the like. The external connecting member is, for example, a wire made of aluminum, gold, or copper, or a clip made of a copper plate.

As shown in FIG. 3, a plurality of trenches TR are formed in the semiconductor substrate SUB of the cell region CR. The plurality of trenches TR are formed in a stripe-like shape, extend in the Y direction, and adjoin each other in the X direction.

As also shown in the A-A cross section of FIG. 4, inside the trench TR, a field plate electrode FP is formed at the lower portion of the trench TR, and a gate electrode GE is formed at the upper portion of the trench TR. The field plate electrode FP and the gate electrode GE extend in the Y-direction along the trench TR.

As also shown in the B-B section in FIG. 4, a part of the field plate electrode FP of the cell region CR forms a lead-out portion FPa. The field plate electrode FP constituting the lead-out portion FPa is formed not only in the lower portion of the trench TR but also in the upper portion of the trench TR inside the trench.

In the cell region CR, a hole CH3 is formed on the lead-out portion FPa. The lead-out portion FPa is electrically connected to the source electrode SE via the hole CH3. In the cell region CR, a hole CH1 is formed on the body region PB and the source region NS, which will be described later. The body region PB and the source region NS are electrically connected to the source electrode SE via the hole CH1. In the outer peripheral region OR, a hole CH2 is formed on the gate electrode GE. The gate electrode GE is electrically connected to the gate wiring GW via the hole CH2.

A cross-sectional configuration of the semiconductor device 100 will be described below with reference to FIG. 4.

As shown in FIG. 4, the semiconductor device 100 comprises an n-type semiconductor substrate SUB having an upper surface TS and a lower surface BS. The semiconductor substrate SUB is made of n-type silicon. The semiconductor substrate SUB has a low concentration n-type drift region NV. In the first embodiment, the n-type semiconductor substrate SUB itself constitutes the drift-region NV. The semiconductor substrate SUB may be a stack of an n-type silicon substrate and an n-type semiconductor layer grown on the n-type silicon substrate while introducing phosphorus (P) by an epitaxial growth method. In that case, the low-concentration n-type semiconductor layer constitutes the drift region NV, and the high-concentration n-type silicon substrate constitutes the drain region ND.

The semiconductor substrate SUB has an n-type drain-region ND so as to reach a predetermined depth from the lower surface BS of the semiconductor substrate SUB toward the upper surface TS of the semiconductor substrate SUB. The drain region ND has a higher impurity concentration than the drift region NV. A drain electrode DE is formed on the lower surface BS of the semiconductor substrate SUB. The drain electrode DE consists of, e.g., a single layer of a metallic membrane, such as an aluminum membrane, a titanium membrane, a nickel membrane, a gold membrane or a silver membrane, or a laminated membrane with these metallic membranes laminated accordingly. The drain region ND and the drain electrode DE are formed over the cell region CR and the outer peripheral region OR. The drain potential is supplied to the semiconductor substrate SUB (the drain region ND, the drift region NV) from the drain electrode DE.

In the semiconductor substrate SUB, a plurality of trenches TR are formed which reach a predetermined depth from the upper surface TS of the semiconductor substrate SUB toward the lower surface BS of the semiconductor substrate SUB. The depth of the trench TR is, for example, 5 μm (5 micrometers) or more and 7 μm (7 micrometers) or less.

As shown in A-A cross section of FIG. 4, in the trench TR, a field plate electrode FP is formed in a lower portion of the trench TR via the insulating film IF1 and the embedded insulating film EF1. The position of the upper surface of the insulating film IF1 is lower than the position of the upper surface of the field plate FP.

The embedded insulating film EF1 is formed inside the trench TR on the insulating film IF1. The gate insulating film GI is formed inside the trench TR on the embedded insulating film EF1. An insulating film IF2 is formed so as to cover the field plate electrode FP exposed from the embedded insulating film EF1. A gate-electrode GE is formed via the insulating film IF2. Each of the field plate electrode FP and the gate electrode GE is formed of, for example, an n-type doped polycrystalline silicon film. The impurity concentration of the polycrystalline silicon film is higher than the impurity concentration of the semiconductor substrate SUB (the drift-region NV).

A part of the gate electrode GE is also formed in a space between the field plate electrode FP and semiconductor substrate SUB and surrounded by the embedded insulating films EF1, the gate insulating film GI, and the insulating film IF2. As described later with reference to FIG. 6, a part of such the gate electrode GE is referred to as an embedded portion GEa.

The insulating film IF1 and the embedded insulating film EF1 are formed between the semiconductor substrate SUB and the field plate electrode FP. The insulating film IF2 is formed between the gate electrode GE and the field plate electrode FP. The gate insulating film GI is formed between the semiconductor substrate SUB and the gate electrode GE. With these films, the semiconductor substrate SUB, the gate electrode GE, and the field plate electrode FP are electrically insulated from each other.

Further, an insulating film IF3 is formed on the gate electrode GE, and the insulating film IF3 is mainly used as a protective film for protecting the cell region CR when forming another semiconductor element such as a resistive element in a region other than the cell region CR. Therefore, it is not necessary to form the insulating film IF3 if there is no need to form other semiconductor device.

The insulating film IF1, the embedded insulating film EF1, the insulating film IF2, the insulating film IF3, and the gate insulating film GI are made of, for example, a silicon-oxide film. The thickness of each of the insulating film IF1 and the embedded insulating film EF1 is greater than the thickness of each of the insulating films IF2 and gate insulating film GI, and is, for example, greater than or equal to 400 nm and less than or equal to 600 nm. The thickness of each of the insulating film IF2 and the gate insulating film GI is, for example, not less than 50 nm and not more than 70 nm. These thicknesses are thicknesses inside the trench TR and are thicknesses in the X-direction.

As shown in FIG. 5, the gate insulating film GI and the insulating film IF2 are stacked films each including a silicon oxide film OX1 and a silicon oxide film OX2.

The semiconductor substrate SUB has a p-type body region PB that reaches a predetermined depth from the upper surface TS of the semiconductor substrate SUB toward the lower surface BS of the semiconductor substrate SUB. The depth of the body region PB from the upper surface TS of the semiconductor substrate SUB is shallower than the trench TR from the upper surface TS of the semiconductor substrate SUB. In the body region PB, an n-type source region NS is formed. The source region NS has a higher impurity concentration than the drift region NV.

An interlayer insulating film IL is formed on the upper surface TS of the semiconductor substrate SUB so as to cover the trench TR. The interlayer insulating film IL is formed of, for example, a silicon oxide film. The thickness of the interlayer insulating film IL is, for example, 700 nm or more and 900 nm or less.

In the interlayer insulating film IL, a hole CH1 extending through the interlayer insulating film IL and the source region NS and reaching the body region PB is formed. At the bottom of the hole CH1, a high concentration diffusion region PR is formed in the body region PB. The high concentration diffusion region PR has a higher impurity concentration than the body region PB. The high concentration diffusion region PR is mainly provided to reduce the contact-resistance with the plug PG and to prevent latch-up.

A source electrode SE is formed on the interlayer insulating film IL. The source electrode SE is electrically connected to the source region NS, the body region PB, and the high concentration diffusion region PR via the hole CH1 and supplies a source potential to these impurity regions.

As shown in B-B cross-section of FIG. 4, a portion of the field plate electrode FP forms a lead-out portion FPa of the field plate electrode FP. The positions of the respective upper surfaces of the insulating film IF1 and the embedded insulating film EF1 in contact with the lead-out portion FPa are higher than the positions of the respective upper surfaces of the insulating film IF1 and the embedded insulating film EF1 in contact with the field plate electrode FP other than the lead-out portion FPa.

An insulating film IF2 is formed so as to cover the lead-out portion FPa exposed from the embedded insulating film EF1. An insulating film IF3 is formed on the embedded insulating film EF1, but it is not necessary to form the insulating film IF3 as described above. Further, a body region PB is formed in the semiconductor substrate SUB adjoining the lead-out portion FPa, but the source region NS is not formed in this body region PB.

In the interlayer insulating film IL, a hole CH3 that extends through the interlayer insulating film IL, the insulating film IF3, and the insulating film IF2 and that reaches the lead-out portion FPa is formed. The source electrode SE is electrically connected to the lead-out portion FPa via the hole CH3, and supplies a source potential to the field plate electrode FP.

Although not illustrated here, in the interlayer insulating film IL, a hole CH2 that extends through the interlayer insulating film IL and the insulating film IF3 and that reaches the gate electrode GE is formed. The gate wiring GW is electrically connected to the gate electrode GE via the hole CH2 and supplies a gate potential to the gate electrode GE.

Inside each of the hole CH1, CH2, CH3, a plug PG is embedded. The plug PG is formed of, for example, a barrier metal film and a conductive film formed on the barrier metal film. The barrier metal film is formed of a laminated film of a titanium film and a titanium nitride film. The conductive film is, for example, a tungsten film.

The source electrode SE and the gate wiring GW are formed of, for example, a barrier metal film and a conductive film formed on the barrier metal film. The barrier metal film is, for example, a titanium tungsten film, and the conductive film is, for example, an aluminum alloy film to which copper or silicon is added.

### <Manufacturing Method of Semiconductor Device>

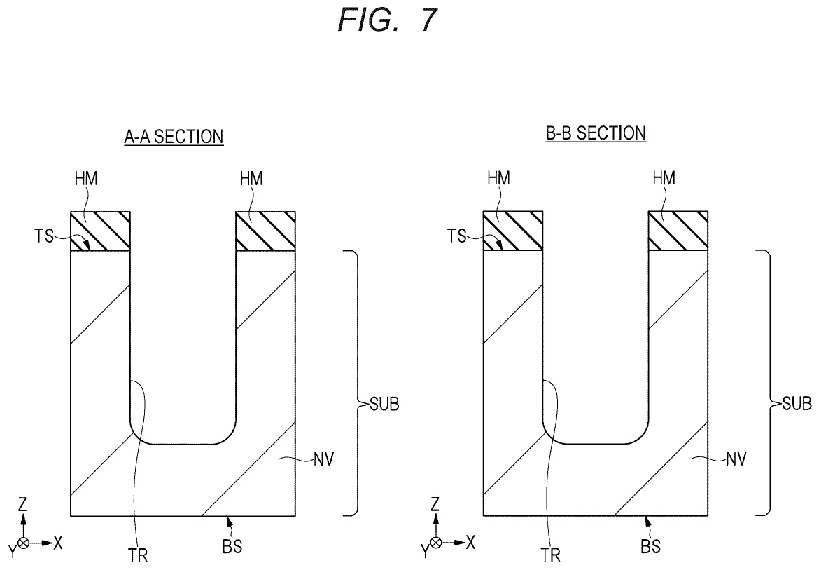

The respective manufacturing steps included in the manufacturing method of the semiconductor device 100 will be described below with reference to FIG. 7 to FIG. 23.

As shown in FIG. 7, first, an n-type semiconductor substrate SUB having an upper surface TS and a lower surface BS is prepared. As mentioned above, the semiconductor substrate SUB may be a stack of an n-type silicon substrate and an n-type semiconducting layer formed on the silicon substrate by epitaxial growth.

Next, a silicon-oxide film, for example, is formed on the semiconductor substrate SUB by, e.g., CVD (Chemical Vapor Deposition). Next, the silicon oxide film is patterned by a photolithography technique and an anisotropic etch process to form a hard mask HM. Next, an anisotropic etch process using the hard mask HM is performed to form a trench TR in the semiconductor substrate SUB so as to reach a predetermined depth from the upper surface TS of the semiconductor substrate SUB toward the lower surface BS of the semiconductor substrate SUB. Thereafter, the hard mask HM is removed by, for example, a wet etching process using a hydrofluoric acid-containing solution.

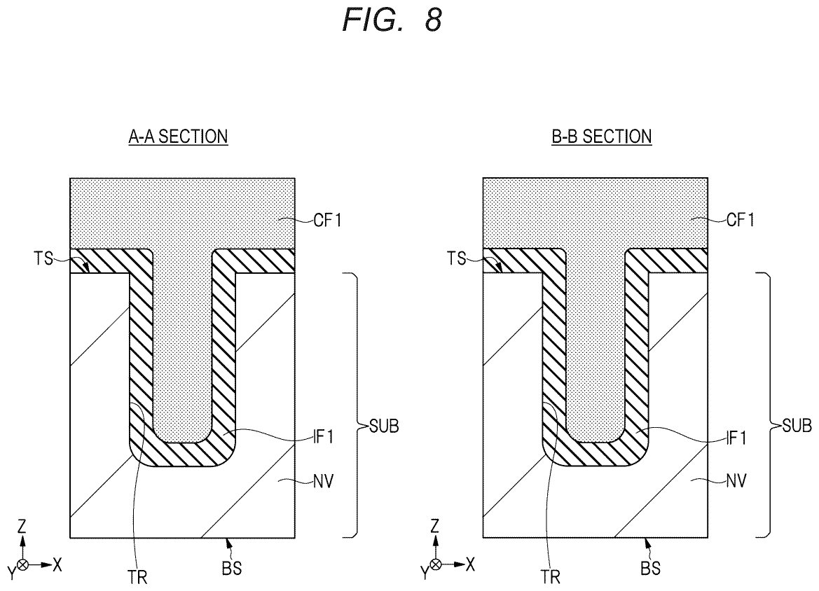

Next, as shown in FIG. 8, an insulating film IF1 is formed inside the trench TR and on the upper surface TS of the semiconductor substrate SUB. The insulating film IF1 is, for example, a silicon-oxide film formed by thermal oxidation treatment. The thickness of the insulating film IF1 on the upper surface TS of the semiconductor substrate SUB is, for example, 400 nm or more and 600 nm or less. The insulating film IF1 may be a stacked film of a first silicon oxide film formed by thermal oxidation treatment and a second silicon oxide film formed by film formation treatment using a CVD method on the first silicon oxide film.

Next, a conductive film CF1 is formed on the insulating film IF1 by a film forming process using, for example, a CVD method so as to fill the inside of the trench TR. The conductive film CF1 is, for example, an n-type polycrystalline silicon film. The impurity concentration of the polycrystalline silicon film is higher than the impurity concentration of the semiconductor substrate SUB (the drift region NV). In order to satisfactorily embed the conductive film CF1 in the trench TR, the conductive film CF1 may be formed in a plurality of times, for example, as in the formation of the first polycrystalline silicon film and the formation of the second polycrystalline silicon film.

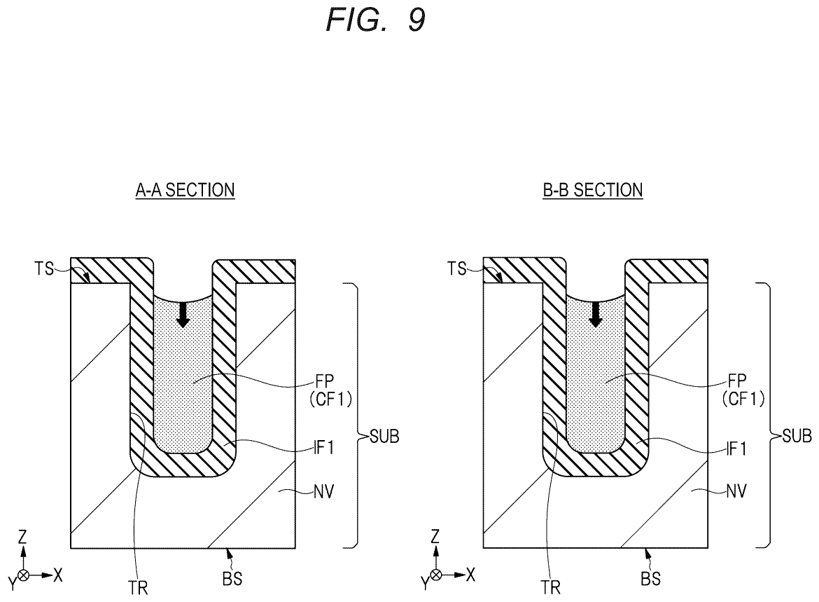

Next, as shown in FIG. 9, the conductive film CF1 left inside the trench TR is formed as a field plate electrode FP by removing the conductive film CF1 located outside the trench TR.

Specifically, first, the conductive film CF1 formed outside the trench TR is removed by a polishing process using, for example, CMP (Chemical Mechanical Polishing). Next, an anisotropic etch process using, for example, SF₆ gas is performed to retract the position of the upper surface of the conductive film CF1 in the trench TR toward the bottom of the trench TR (arrow in FIG. 9). As a result, the conductive film CF1 left in the trench TR is formed as the field plate electrode FP.

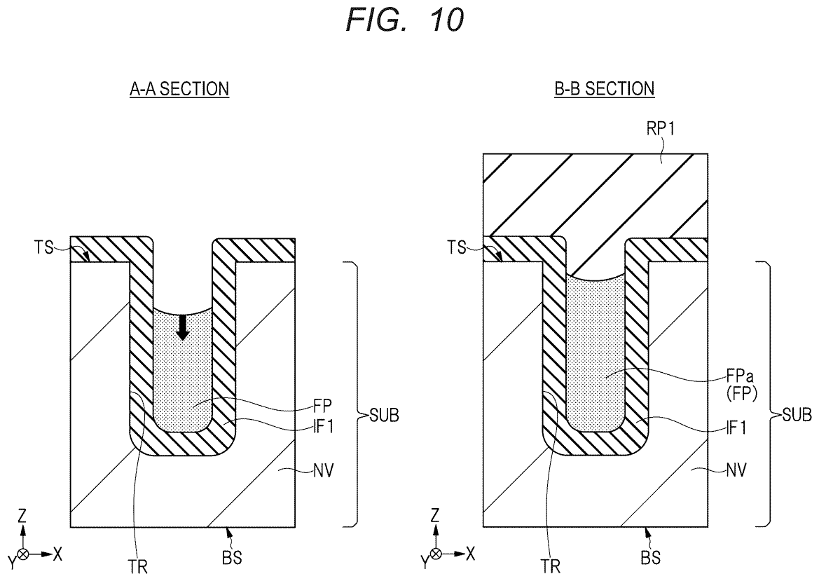

Next, as shown in FIG. 10, the other part of the field plate electrode FP is selectively removed so that a part of the field plate electrode FP is left as the lead-out portion FPa.

Specifically, first, as shown in B-B cross section, a resist pattern RP1 that selectively covers a portion of the field plate electrode FP that becomes the lead-out portion FPa is formed. Next, using the resist pattern RP1 as a mask, an anisotropic etch process using, for example, SF₆ gas is performed to remove the other portion of the field plate electrode FP that does not become the lead-out portion FPa. That is, as shown in A-A cross section of FIG. 10, the position of the upper surface of the field plate electrode FP that does not become the lead-out portion FPa is selectively retracted toward the bottom of the trench TR (arrow in FIG. 10). A portion of the field plate electrode FP that has not been retracted becomes the lead-out portion FPa. Thereafter, the resist pattern RP1 is removed by ashing.

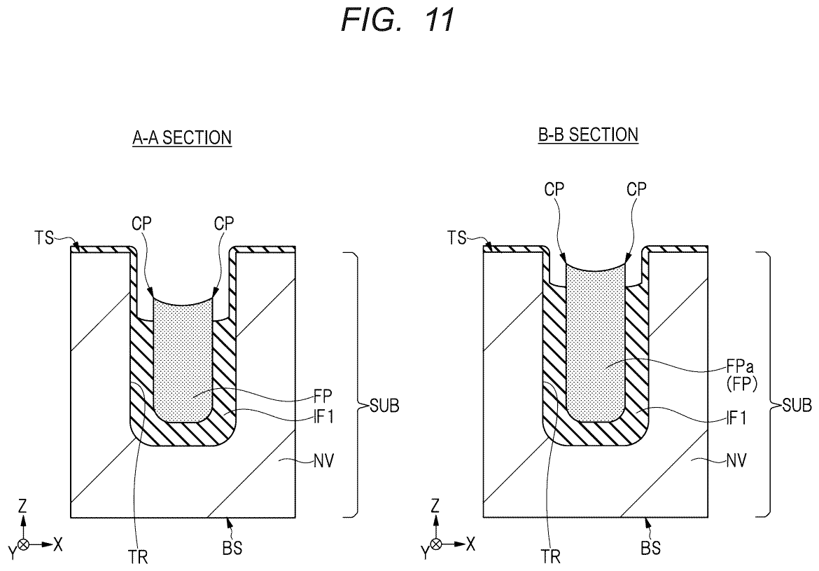

Next, as shown in FIG. 11, the insulating film IF1 is subject to isotropic etching to reduce the thickness of the insulating film IF1 and to expose the upper portion of the field plate electrode FP from the insulating film IF1. At this time, the upper portion of the lead-out portion FPa is also exposed from the insulating film IF1. The isotropic etching process is, for example, a wet etching process using a solution containing hydrofluoric acid. The upper portion of the field plate electrode FP and the upper portion of the lead-out portion FPa are portions including the upper surface of the field plate electrode FP and the upper surface of the lead-out portion FPa.

At this point, the insulating film IF1 on the upper surface TS of the semiconductor substrate SUB and inside the trench TR has not been completely removed. In addition, the corners CP of each of the upper portion of the field plate electrodes FP and the lead-out portion FPa exposed from the insulating film IF1 are processed into protrusions by the anisotropic etch process of FIGS. 9 and 10.

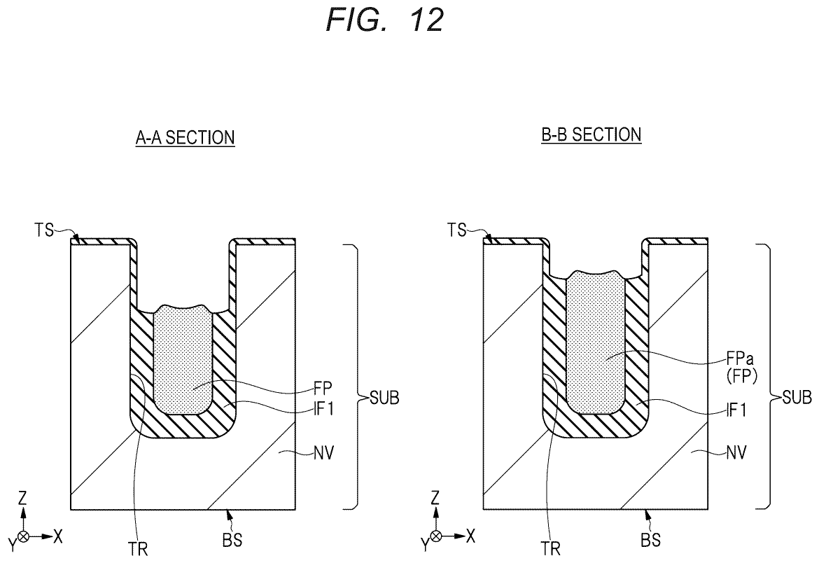

Next, as shown in FIG. 12, an isotropic etch process is performed on the upper portion of each of the field plate electrode FP and the lead-out portion FPa exposed from the insulating film IF1. This isotropic etching process is a chemical dry etching process using CF₄ gase. Thereby, the upper corners CP of each of the field plate electrode FP and the lead-out portion FPa are chamfered or rounded.

In this isotropic etching process, the thinned insulating film IF1 on the upper surface TS of the semiconductor substrate SUB and inside the trench TR functions as an etching stopper.

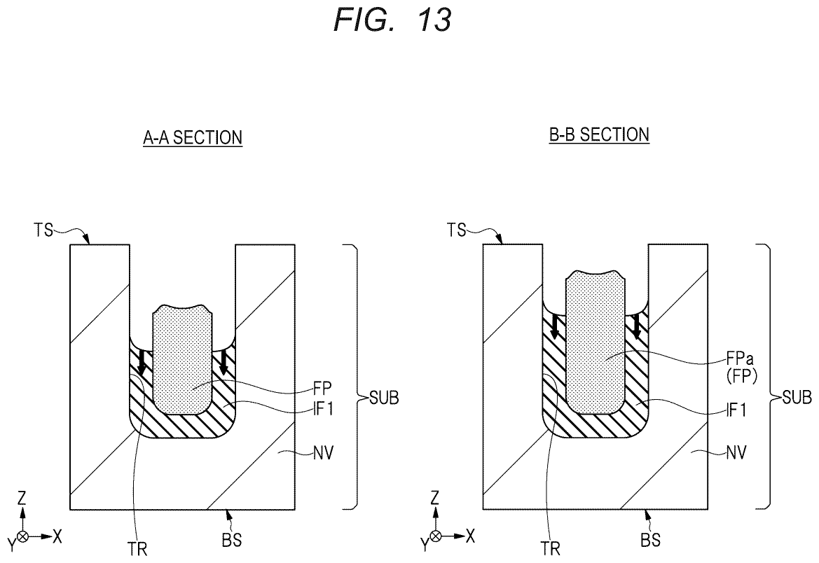

Next, as shown in FIG. 13, the insulating film IF1 is subjected to an isotropic etch process using solutions containing hydrofluoric acid. Accordingly, the insulating film IF1 located on the upper surface TS (that is, outside the trench TR) of the semiconductor substrate SUB is removed and the insulating film IF1 located inside the trench TR is retracted toward the bottom of the trench TR so that the position of the upper surface of the insulating film IF1 located inside the trench TR is further lower than the position of the upper surface of the field plate electrode FP in the cross-sectional view (arrow in FIG. 13).

At this point, the position of the upper surface of the insulating film IF1 in contact with the field plate electrode FP other than the lead-out portion FPa is lower than the position of the upper surface of the insulating film IF1 in contact with the lead-out portion FPa.

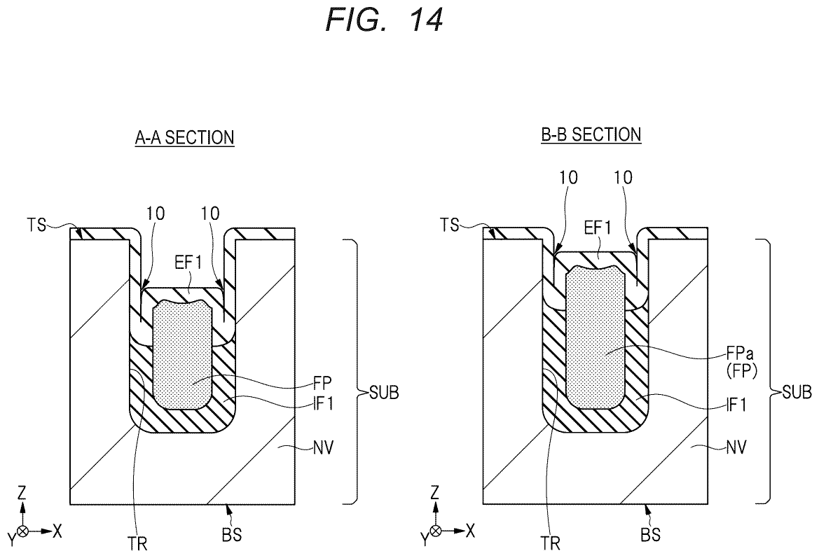

Next, as shown in FIG. 14, an embedded insulating film EF1 is formed on the upper surface TS of the semiconductor substrate SUB and inside the trench TR by a film forming process using, for example, a CVD method so as to cover the field plate electrode FP and the insulating film IF1. The embedded insulating film EF1 is an insulating film such as, for example, a silicon-oxide film. The thickness of the embedded insulating film EF1 on the upper surface TS of the semiconductor substrate SUB is, for example, 200 nm or more and 300 nm or less.

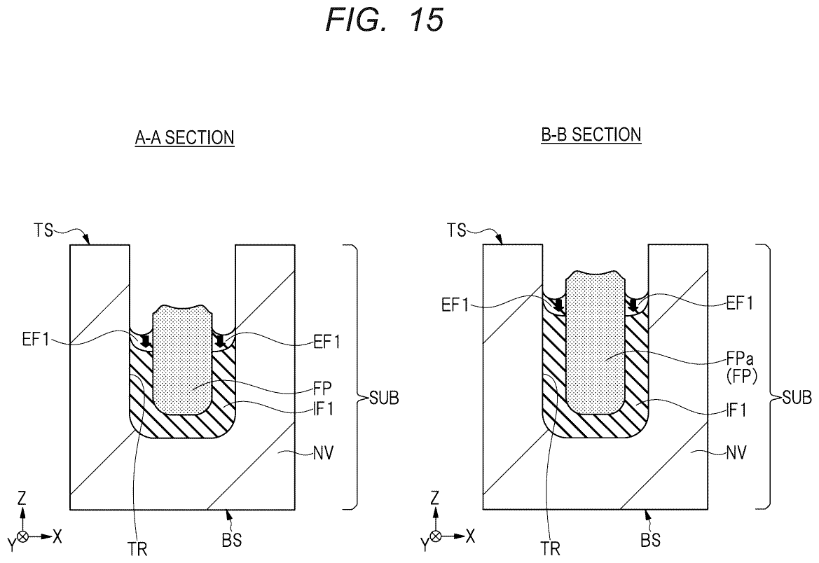

Next, as shown in FIG. 15, the embedded insulating film EF1 is subject to isotropic etching using solutions containing hydrofluoric acid. Accordingly, the embedded insulating film EF1 located on the upper surface TS of the semiconductor substrate SUB is removed and the embedded insulating film EF1 located inside the trench TR is retracted toward the bottom of the trench TR so that the position of the upper surface of the embedded insulating film EF1 located inside the trench TR is lower than the position of the upper surface of the field plate electrode FP in the cross-sectional view (arrow in FIG. 15). The isotropic etching process is, for example, a wet etching process using a solution containing hydrofluoric acid.

Here, the isotropic etching process proceeds from the starting point 10 shown in FIG. 14. The starting point 10 is located between the field plate electrode FP and the semiconductor substrate SUB (near the middle). Specifically, the starting point 10 is located between a side portion of the semiconductor substrate SUB located next to the field plate electrode FP in the X-direction shown in FIG. 14 and the field plate electrode FP. Therefore, at the end of the isotropic etch process, as shown in FIG. 15, the upper surface of the embedded insulating film EF1 has a curved surface shape that rises as it approaches the side of the semiconductor substrate SUB and rises as it approaches the field plate electrode FP.

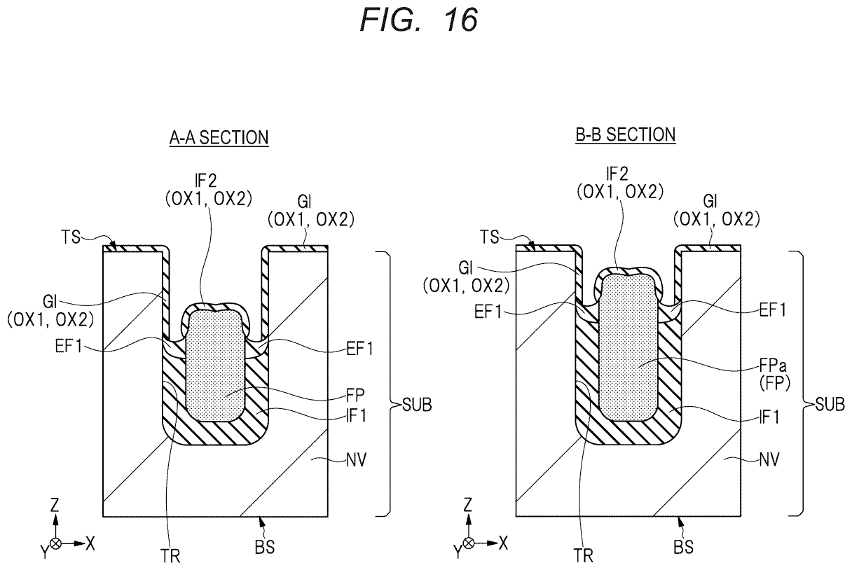

Next, as shown in FIG. 16, a gate insulating film GI is formed inside the trench TR located on the embedded insulating film EF1, and an insulating film IF2 is formed so as to cover the field plate electrode FP exposed from the embedded insulating film EF1.

As described with respect to FIG. 5, the gate insulating film GI and the insulating film IF2 are stacked films including the silicon oxide film OX1 and the silicon oxide film OX2, respectively. These manufacturing steps thereof will be described in detail below.

First, a silicon oxide film OX1 is formed inside the trench TR on the embedded insulating film EF1, and a silicon oxide film OX1 is formed so as to cover the field plate electrode FP exposed from the embedded insulating film EF1. The silicon oxide film OX1 is formed by a dry oxidation treatment, which is a kind of thermal oxidation treatment. That is, it is not a wet oxidation treatment which is also a kind of thermal oxidation treatment. The dry oxidation treatment is performed, for example, using oxygen gas at a condition at 1000 degrees Celsius or higher and 1200 degrees Celsius or lower. The thickness of the silicon oxide film OX1 is, for example, 25 nm or more and 35 nm or less.

Next, a silicon oxide film OX2 is formed on the silicon oxide film OX1 by a film forming process using a CVD method. The silicon oxide film OX2 is a TEOS (Tetra Ethoxy Silane) film and has a thickness of, for example, 25 nm or more and 35 nm or less. Thereafter, a heat treatment for densifying the film quality of the silicon oxide film OX2 may be performed. Such heat treatment is performed in a nitrogen gas atmosphere or an oxygen gas atmosphere, for example, at a temperature of 900 degrees Celsius or higher and 1000 degrees Celsius or less. The silicon oxide film OX2 is also formed on the embedded insulating film EF1.

The insulating film in contact with the field plate electrodes FP and semiconductor substrate SUB is preferably not a silicon oxide film OX2 but a silicon oxide film OX1. The silicon oxide film OX1 formed by the dry oxidation treatment can improve the interface state between the gate insulating film GI and the semiconductor substrate SUB and improve the interface state between the insulating film IF2 and the field plate electrode FP than the silicon oxide film OX2 formed by the film formation treatment using CVD method.

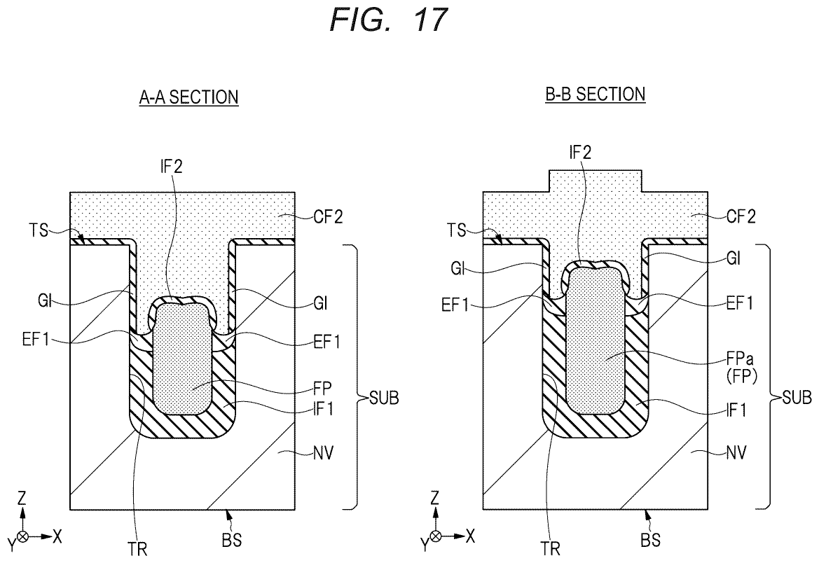

Next, as shown in FIG. 17, a conductive film CF2 is formed on the gate insulating film GI, the insulating film IF2, and the embedded insulating film EF1 by a film forming process using, for example, a CVD method so as to fill the inside of the trench TR. The conductive film CF2 is, for example, an n-type polycrystalline silicon film. The impurity concentration of the polycrystalline silicon film is higher than the impurity concentration of semiconductor substrate SUB (the drift region NV).

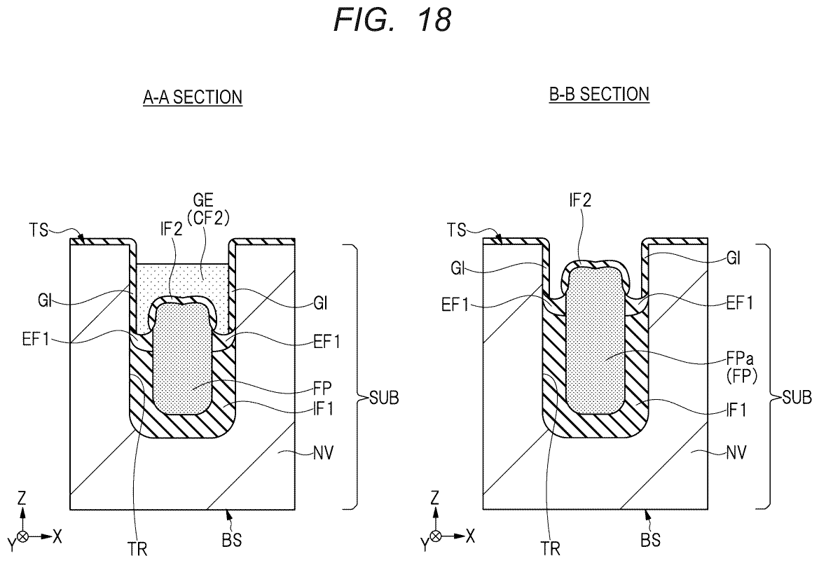

Next, as shown in FIG. 18, the conductive film CF2 is subjected to a polishing treatment using a CMP method. As a result, the thickness of the conductive film CF2 is reduced, and the upper surface of the conductive film CF2 is planarized. Next, an anisotropic etch process is performed on the conductive film CF2 to remove the conductive film CF2 located outside the trench TR. Accordingly, the conductive film CF2 left in the trench TR above the field plate electrode FP is formed as the gate electrode GE.

In order to completely remove the conductive film CF2 outside the trench TR, the anisotropic etching process is performed by over-etching. Therefore, as shown in A-A cross section of FIG. 18, the position of the upper surface of the gate electrode GE is lower than the position of the upper surface TS of the semiconductor substrate SUB. Further, by this anisotropic etch process, the conductive film CF2 formed on the embedded insulating film EF1 and the insulating film IF2 in contact with the lead-out portion FPa is removed.

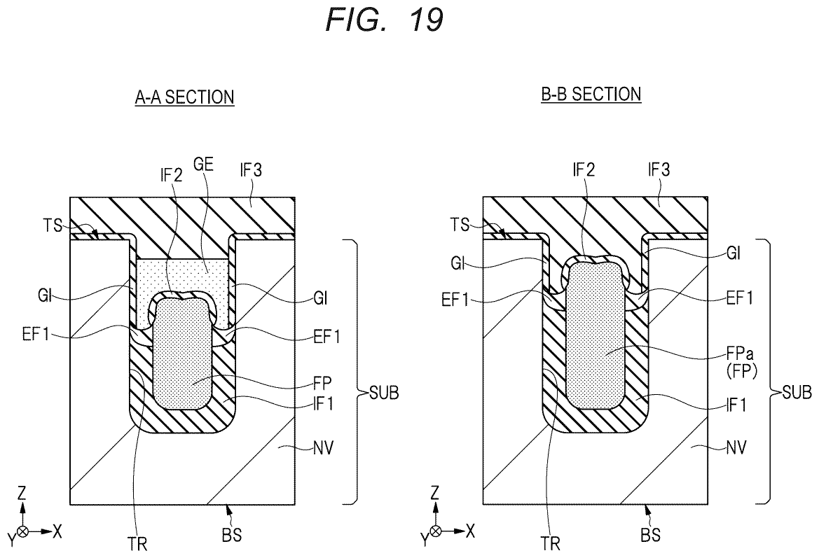

Next, as shown in FIG. 19, an insulating film IF3 is formed on the gate insulating film GI, the gate-electrode GE, the insulating film IF2, and the embedded insulating film EF1 by a film forming process using, for example, a CVD method so as to cover the trench TR.

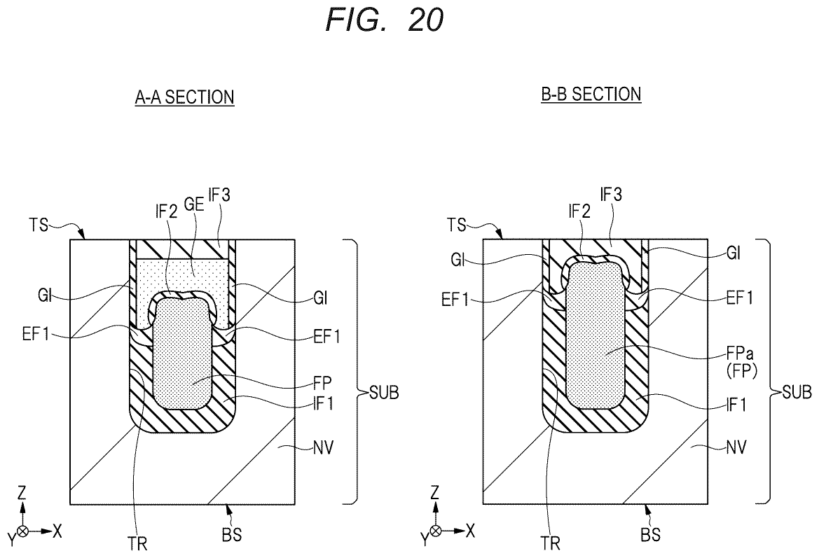

Next, as shown in FIG. 20, the insulating film IF3 is subjected to an anisotropic etch process. As a result, the insulating film IF3 and the gate insulating film GI on the upper surface TS of the semiconductor substrate SUB are removed. As shown in A-A cross section, the insulating film IF3 is left on the gate electrode GE so as to be in contact with the gate insulating film GI. As shown in B-B cross section, the insulating film IF3 is left on the insulating film IF2 and the embedded insulating film EF1 so as to be in contact with the gate insulating film GI.

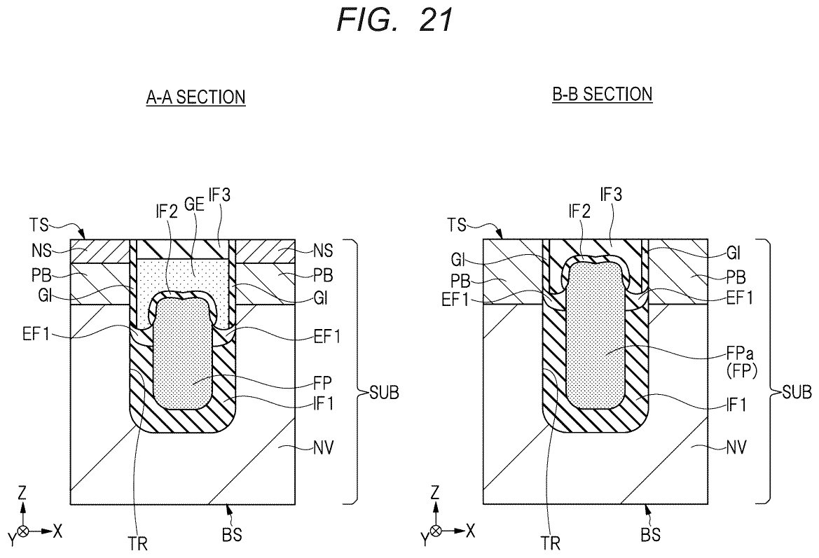

Next, as shown in FIG. 21, a p-type body region PB is selectively formed in the semiconductor substrate SUB by introducing, for example, boron (B) by photolithography and ion-implantation. The body region PB is formed so that the depth from the upper surface TS of the semiconductor substrate SUB is shallower than the depth of the trench TR.

Next, by introducing, for example, arsenic (As) by photolithography and ion implantation, an n-type source region NS is selectively formed in the body region PB of the cell region CR as shown in A-A cross section. Note that, as shown in B-B cross section, the source-region NS is not formed in the body region PB adjoining the lead-out portion FPa. Thereafter, the semiconductor substrate SUB is subjected to a heat treatment to diffuse impurities contained in the source region NS and the body region PB.

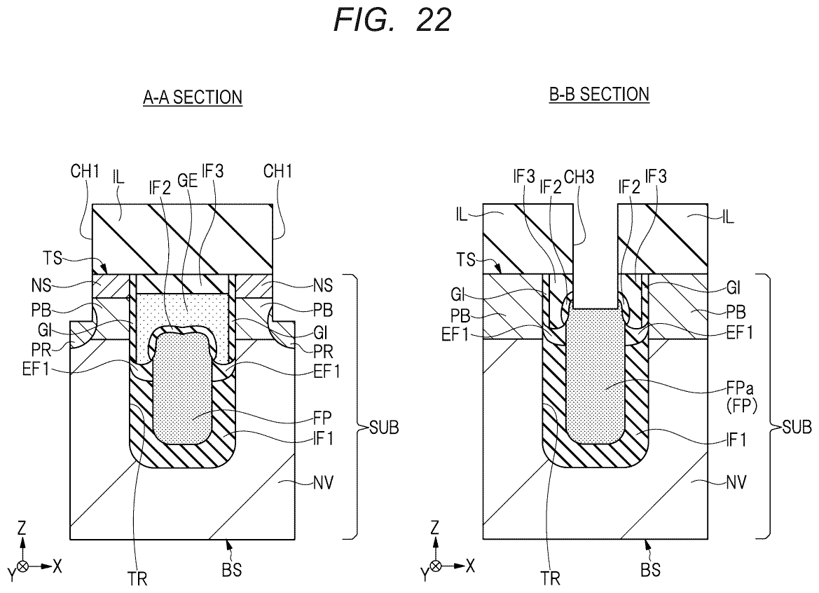

Next, as shown in FIG. 22, an interlayer insulating film IL is formed on the upper surface TS of the semiconductor substrate SUB by, for example, a CVD method so as to cover the trench TR.

Then, holes CH1, CH2, and CH3 are formed in the interlayer insulating film IL. Specifically, first, a resist pattern having a pattern for opening the semiconductor substrate SUB in which the source region NS is formed is formed on the interlayer insulating film IL. Next, an anisotropic etch process is performed using the resist pattern as a mask to form a hole CH1 extending through the interlayer insulating film IL and the source region NS and reaching the inside of the body region PB. Next, a p-type high concentration diffusion region PR is formed by introducing, for example, boron (B) into the body region PB at the bottom of the hole CH1 by the ion-implantation method. Thereafter, the resist pattern is removed by an ashing process.

Next, on the interlayer insulating film IL, a resist pattern having a pattern opening on the lead-out portion FPa and on the gate electrode GE is formed. Next, an anisotropic etch process is performed using the resist pattern as a mask to form a hole CH3 that extends through the interlayer insulating film IL, the insulating film IF3, and the insulating film IF2 and reaches the lead-out portion FPa. Although not illustrated here, in the step of forming the hole CH3, a hole CH2 that extends through the interlayer insulating film IL and the insulating film IF3 and reaches the gate electrode GE is also formed. Thereafter, the resist pattern is removed by an ashing process.

The order in which the hole CH1 is formed and the order in which the hole CH2 and the hole CH3 are formed may be exchanged.

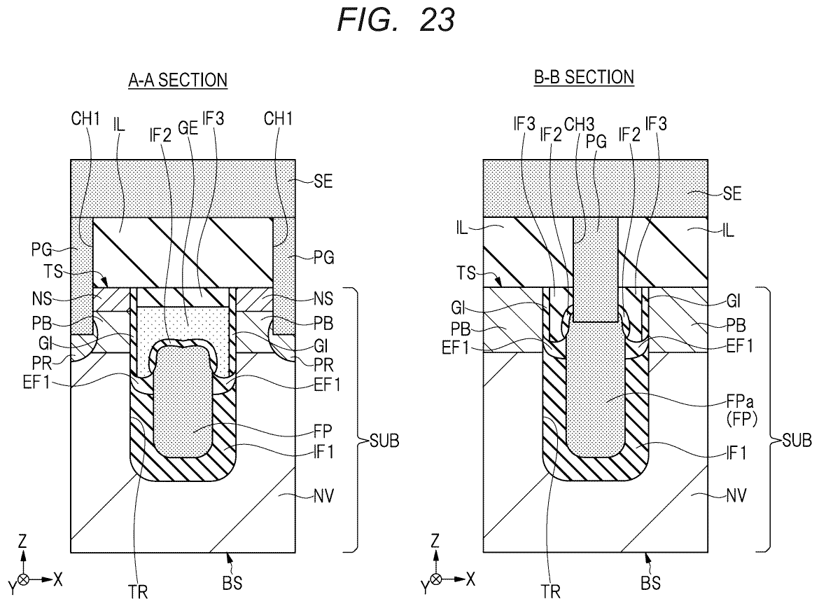

Next, as shown in FIG. 23, a plug PG is formed inside each of the hole CH1, CH2, CH3, and the source electrode SE and the gate wiring GW are formed on the interlayer insulating film IL.

Specifically, first, a first barrier metal film is formed on the insides of the holes CH1, CH2, CH3 and the interlayer insulating film IL by a film forming process using a sputtering method or a CVD method. The first barrier metal film is formed of, for example, a laminated film of a titanium nitride film and a titanium film. Next, a first conductive film is formed on the first barrier metal film by a film forming process using a CVD method. The first conductive film is formed of, for example, a tungsten film. Next, the first barrier metal film and the first conductive film formed outside the holes CH1, CH2, CH3 are removed by a CMP method or an anisotropic etch process. As a result, a plug PG formed of the first barrier metal film and the first conductive film is formed so as to fill the insides of the holes CH1, CH2, CH3.

Next, a second barrier metal film is formed on the interlayer insulating film IL by sputtering. The second barrier metal film is formed of, for example, a titanium tungsten film. Next, a second conductive film is formed on the second barrier metal film by sputtering. The second conductive film is, for example, an aluminum alloy film to which copper or silicon is added. Next, the second barrier metal film and the second conductive film are patterned to form the source electrode SE and the gate wiring GW.

Next, although not illustrated here, a protective film made of, for example, a polyimide film is formed on the source electrode SE and the gate wiring GW by, for example, a coating method. By forming openings in parts of the protective film, regions of the source electrode SE and the gate wiring GW that become the source pad SP and the gate pad GP are exposed.

Thereafter, the structure shown in FIG. 4 is obtained through the following manufacturing processes. First, the lower surface BS of the semiconductor substrate SUB is polished as needed. Next, an n-type drain region ND is formed by introducing, for example, arsenic (As) or the like into the lower surface BS of the semiconductor substrate SUB by ion-implantation. When the semiconductor substrate SUB is composed of a stack of an n-type silicon substrate and an n-type semiconductor layer, the high-concentration n-type silicon substrate forms a drain region ND, and thus the forming of the drain region ND by the ion implantation described above can be omitted. Next, a drain electrode DE is formed on the lower surface BS of the semiconductor substrate SUB by a sputtering method.

### Main Features of First Embodiment

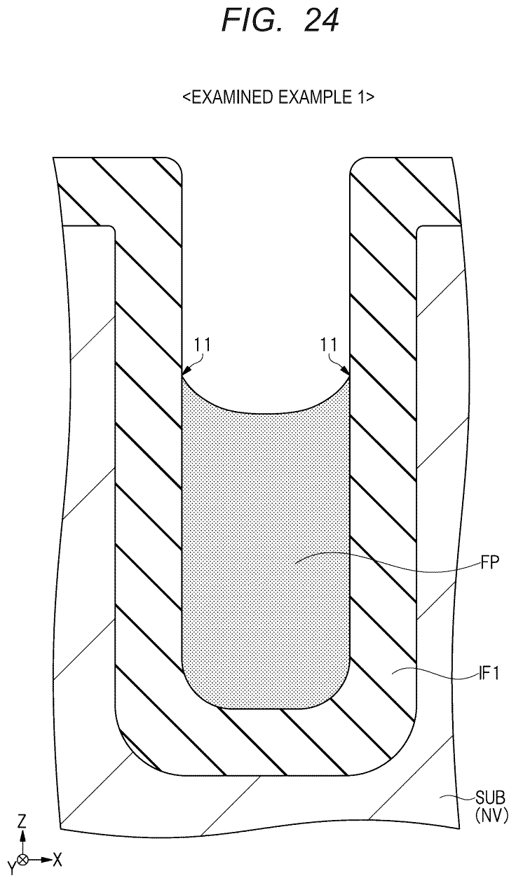

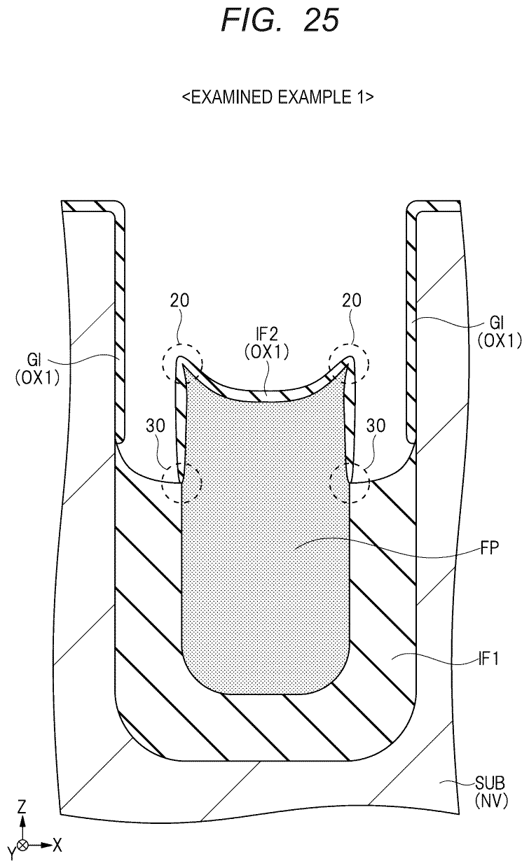

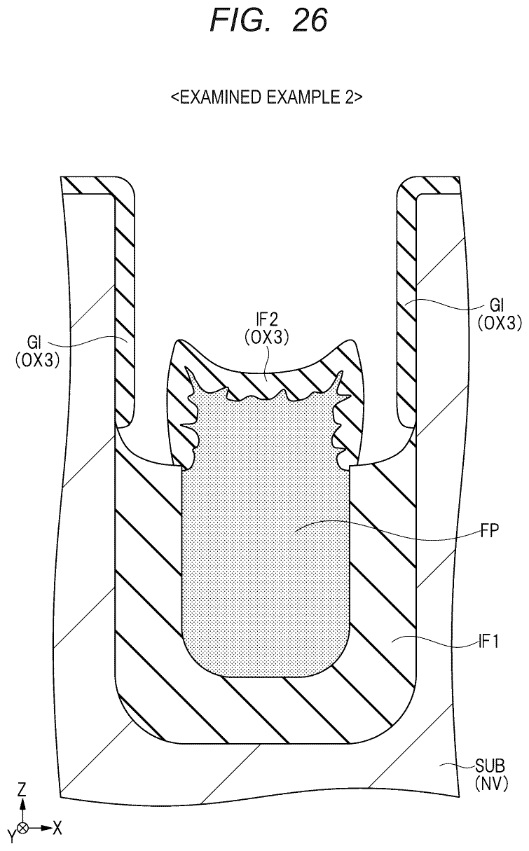

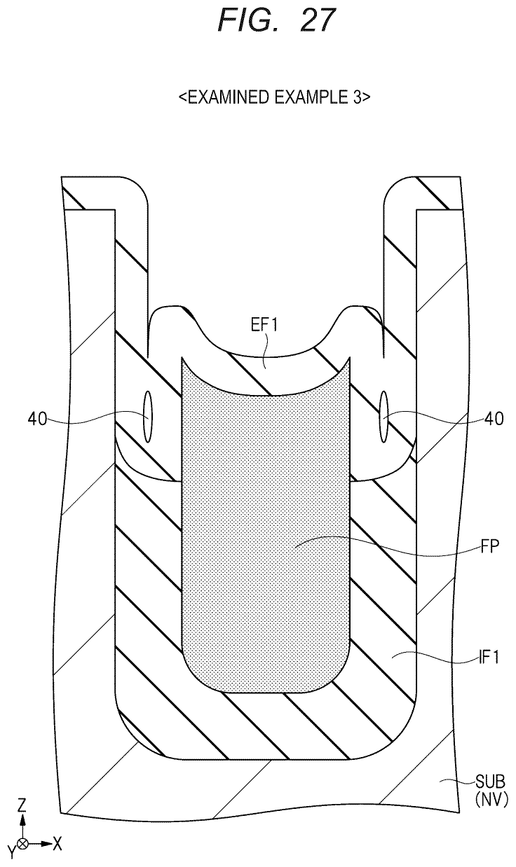

Semiconductor devices of examined example 1, examined example 2, examined example 3, and the main features of the first embodiment will be described below with reference to FIGS. 5, 24, 25, 26, and 27. FIG. 5, FIG. 24, FIG. 25, FIG. 26, and FIG. 27 are main portion cross-sectional views in which the inside of the trench TR corresponding to A-A cross section of FIG. 4 is enlarged.

In examined example 1, as shown in FIG. 24, an insulating film IF1 and a field plate electrode FP are formed inside the trench TR. Next, as shown in FIG. 25, the insulating film IF1 inside the trench TR is retreated by one isotropic etch process. Here, the isotropic etching process proceeds from the starting point 11 shown in FIG. 24. Next, a gate insulating film GI and an insulating film IF2 made of a silicon oxide film OX1 are formed by dry oxidation.

In the examined example 1, unlike the first embodiment, the chemical dry etching process of FIG. 12 is not performed. Thus, the upper corners of the field plate FP remain protruding. Therefore, the electric field tends to concentrate at the protruding portions 20 shown in FIG. 25, and the insulation resistance deteriorates between the gate electrode GE and the field plate electrode FP, and a leakage current tends to be generated.

On the other hand, in the first embodiment, the chemical dry etching process of FIG. 12 is applied. Thus, as shown in FIG. 5, the upper corners of the field plate electrode FP are chamfered or rounded. Therefore, portions where the concentration of the electric field occurs between the gate electrode GE and the field plate electrode FP are made uniform. That is, since the concentration of the electric field is relaxed, the occurrence of the leakage current is suppressed. Therefore, the reliability of the semiconductor device 100 can be improved.

Also, in the examined example 1, the isotropic etch process proceeds from the starting point 11 shown in FIG. 24. Therefore, as shown in FIG. 25, the position of the portion of the upper surface of the insulating film IF1 located inside the trench TR that is in contact with the field plate electrode FP is retracted below the position of the portion in contact with the side portion of the semiconductor substrate SUB. That is, the position of the portion in contact with the field plate FP is retracted toward the bottom of the trench TR. When the insulating film IF2 is formed by performing the dry oxidation treatment in this condition, it is difficult for the oxygen gas to reach, and the thickness of the insulating film IF2 in the vicinity of the insulating film IF1 tends to be locally thin. Therefore, it is difficult to ensure insulation resistance between the gate electrode GE and the field plate electrode FP. Such locations are shown as thin film locations 30 in FIG. 25.

In the examined example 2, in order to ensure the thickness of the thin film portions 30, as shown in FIG. 26, a silicon oxide film OX3 by wet oxidation treatment is applied. The wet oxidation treatment is, for example, a thermal oxidation treatment performed using water vapor under conditions of 850 degrees Celsius or higher and 950 degrees Celsius or lower.

Since the impurity concentration of the polycrystalline silicon film constituting the field plate electrode FP is higher than the impurity concentration of the semiconductor substrate SUB (the drift region NV), the thickness of the insulating film IF2 is more likely to be formed thicker than the thickness of the gate insulating film GI due to the effect of the accelerated oxidation when the wet oxidation treatment is performed. In addition, the thickness of the insulating film IF2 is easily ensured even in the vicinity of the insulating film IF1.

On the other hand, in the wet oxidation treatment, the roughness of the oxidized surface of the field plate electrode FP tends to be rough. Therefore, a portion where the thickness of the insulating film IF2 is locally thin is likely to occur, and the concentration of the electric field is likely to occur at that portion. In addition, it is difficult to reduce the concentration of the electric field also at a protruded portion of the field plate electrode FP.

On the other hand, in the dry oxidation treatment, the effect of the accelerated oxidation is less than that of the wet oxidation treatment, but the roughness of the oxidized surface of the field plate electrode FP is improved. Therefore, a means capable of ensuring insulation resistance at the thin-film portion 30 even when the dry oxidation treatment is applied is required.

Therefore, in the first embodiment, the embedded insulating film EF1 is formed in FIG. 14, and the embedded insulating film EF1 is retreated by an isotropic etch process in FIG. 15. As a consequence, as shown in FIG. 5, the upper surface of the embedded insulating film EF1 has a curved surface shape that rises as approaching the semiconductor substrate SUB and rises as approaching the field plate electrode FP.

Therefore, the thickness can be compensated by the embedded insulating film EF1 even if the thickness of the silicon oxide film OX1 formed by the dry oxidation treatment is thin in the vicinity of the embedded insulating film EF1. Therefore, the insulation resistance can be ensured at the thin film portion 30, and the reliability of the semiconductor device 100 can be improved.

In addition, the exposed area of the field plate electrode FP is reduced because of the embedded insulating film EF1, thus during the dry oxidation process, it is possible to shorten the duration of forming the silicon oxide film OX1 having a predetermined thickness. Therefore, the manufacturing process can be shortened.

In the first embodiment, a stacked film of a silicon oxide film OX1 and a silicon oxide film OX2 is applied to the gate insulating film GI and the insulating film IF2, but the silicon oxide film OX2 is provided mainly for adjusting the thicknesses of the gate insulating film GI and the insulating film IF2. The silicon oxide film OX2 formed by the film forming process using CVD method is more likely to be formed to have a uniform thickness than the silicon oxide film formed by the wet oxidation process. Therefore, it is unlikely to locally generate a portion having a small thickness, and it is easy to suppress the occurrence of the concentration of the electric field.

Note that, since the silicon oxide film OX2 is easily formed to have a uniform thickness, even if the silicon oxide film OX2 is formed on the silicon oxide film OX1 in the examined example 1 of FIG. 25, the thin film portion 30 is still a locally thin portion. Therefore, it is required to compensate for the thickness by an embedded insulating film EF1 such as the first embodiment.

Further, the number of layers of the silicon oxide film stacked on the silicon oxide film OX1 by the film forming process using CVD method is not limited to one layer of the silicon oxide film OX2, but may be a plurality of layers.

Incidentally, the embedded insulating film EF1 is preferably formed after the chemical dry etching process is performed on the field plate electrode FP. For example, as shown in the examined example 3 of FIG. 27, when the upper corner of the field plate electrode FP is processed into a protruding shape, the aspect-ratio is high. Therefore, when the embedded insulating film EF1 is formed by the film forming process by CVD method, there is a possibility that a gap 40 is generated in the embedded insulating film EF1.

When such a gap 40 is present, there is a possibility that an etchant permeates into the gap 40 when the embedded insulating film EF1 is retreated by the isotropic etching process of FIG. 15. In this case, the embedded insulating film EF1 may be etched quickly in the gap 40, and the thickness of the embedded insulating film EF1 may become extremely thin, so that almost all of the embedded insulating film EF1 may be removed. In any case, there is a high possibility that an embedded insulating film EF1 having a desired configuration cannot be formed.

If the corner CP of the upper portion of the field plate electrode FP is chamfered or rounded, as in the first embodiment, the aspect-ratio is reduced, so that the embedding property of the embedded insulating film EF1 is improved and the generation of the gap 40 can be suppressed.

FIG. 6 is a main portion cross-sectional view showing that the semiconductor device 100 of the first embodiment does not have a portion such as the thin film portion 30 of FIG. 25, and the insulation resistance is improved. In FIG. 6, the boundaries of the insulating film IF1, the insulating film IF2, the gate insulating film GI, and the embedded insulating film EF1 are not illustrated. When these insulating films are of the same type, such as a silicon oxide film, these insulating films are considered to be one integrated insulating film IF integrated in the trench TR.

That is, an integrated insulating film IF is formed inside the trench TR so as to be located between each of the semiconductor substrate SUB, the field plate electrode FP, and the gate electrode GE. The semiconductor substrate SUB, the field plate electrode FP, and the gate electrode GE are electrically insulated from each other by the integrated insulating film IF.

A part of the gate electrode GE is also formed as an embedded portion GEa between the field plate electrode FP and the semiconductor substrate SUB.

As described above, one of the main features of the first embodiment is that the upper surface of the embedded insulating film EF1 is curved and rises as it approaches the field plate electrode FP. Therefore, the thickness can be compensated by the embedded insulating film EF1 even if the thickness of the insulating film IF2 is small in the vicinity of the embedded insulating film EF1.

In other words, as shown in FIG. 6, the thickness T1 of the integrated insulating film IF formed between the embedded portion GEa and the field plate electrode FP is thickest between the deepest portion of the embedded portion GEa and the field plate electrode FP. For example, the thickness T2 of the integrated insulating film IF at a depth near the middle between the uppermost portion of the field plate electrode FP and the deepest portion of the embedded portion GEa is smaller than the thickness T1.

In addition, the upper surface of the embedded insulating film EF1 rises as approaching the side of the semiconductor substrate SUB. The thickness T3 of the integrated insulating film IF formed between the embedded portion GEa and the side of the semiconductor substrate SUB is the thickest between the deepest portion of the embedded portion GEa and the semiconductor substrate SUB. For example, the thickness T4 of the integrated insulating film IF at a depth near the middle between the uppermost portion of the field plate electrode FP and the deepest portion of the embedded portion GEa is smaller than the thickness T3.

Since the integrated insulating film IF is formed in this manner, not only the insulation resistance between the semiconductor substrate SUB and the gate electrode GE but also the insulation resistance between the field plate electrode FP and the gate electrode GE can be ensured.

Although the present invention has been described in detail based on the above-described embodiments, the present invention is not limited to the above-described embodiments and can be variously modified without departing from the gist thereof.

For example, in the above first embodiment, after the field plate electrode FP is formed as shown in FIG. 9, the isotropic etching process is performed on the upper portions of the field plate electrode FP and the lead-out portion FPa, respectively, exposed from the insulating film IF1 as shown in FIG. 12, prior to the isotropic etching process is performed on the insulating film IF1 as shown in FIG. 13. However, the isotropic etch process performed on the upper portion of each of the field plate electrode FP and the lead-out portion FPa shown in FIG. 12 may be omitted. However, in order to more reliably suppress the generation of the above-described gap 40, it is preferable to perform an isotropic etching process on the upper portion of each of the field plate electrode FP and the lead-out portion FPa after forming the field plate electrode FP as in the first embodiment and prior to performing an isotropic etching process on the insulating film IF1.

What is claimed is:

1. A method of manufacturing a semiconductor device, comprising:
(a) preparing a semiconductor substrate of a first conductivity type having an upper surface and a lower surface;
(b) after (a), forming a trench in the semiconductor substrate so as to reach a predetermined depth from the upper surface of the semiconductor substrate to the lower surface of the semiconductor substrate;
(c) after (b), forming a first insulating film inside the trench and on the upper surface of the semiconductor substrate;
(d) after (c), forming a field plate electrode on the first insulating film inside the trench;
(e) after (d), removing the first insulating film located on the upper surface of the semiconductor substrate and retreating the first insulating film inside the trench toward the bottom of the trench so that, in a cross-sectional view, the position of the upper surface of the first insulating film located inside the trench is lower than the position of the upper surface of the field plate electrode;
(f) after (e), forming an embedded insulating film on the upper surface of the semiconductor substrate and inside the trench so as to cover the field plate electrode and the first insulating film;
(g) after (f), removing the embedded insulating film located on the upper surface of the semiconductor substrate and retreating the embedded insulating film inside the trench toward the bottom of the trench so that, in a cross-sectional view, the position of the upper surface of the embedded insulating film located inside the trench is lower than the position of the upper surface of the field plate electrode;
(h) after (g), forming a gate insulating film inside the trench located on the upper surface of the embedded insulating film by performing a dry oxidation treatment and forming a second insulating film so as to cover the field plate electrode exposed from the embedded insulating film by (g); and
(i) after (h), forming a gate electrode on the field plate electrode via the second insulating film inside the trench.

2. The method of manufacturing a semiconductor device according to claim 1, wherein (f) is performed by a film forming process using a CVD method, and (g) is performed by an isotropic etch process.

3. The method of manufacturing a semiconductor device according to claim 2, wherein the embedded insulating film is a silicon oxide film, and the isotropic etch process in (g) is performed using a hydrofluoric acid-containing solution.

4. The method of manufacturing a semiconductor device according to claim 2, wherein, after (g), the upper surface of the embedded insulating film has a curved surface shape that rises as it approaches the semiconductor substrate and rises as it approaches the field plate electrode.

5. The method of manufacturing a semiconductor device according to claim 1, wherein (h) comprises:
(h1) forming a first silicon oxide film inside the trench located on the upper surface of the embedded insulating film by the dry oxidation treatment performed using oxygen gas under a condition of 1000 degrees Celsius or higher and 1200 degrees Celsius or lower, and forming the first silicon oxide film so as to cover the field plate electrode exposed from the embedded insulating film by (g); and
(h2) forming a second silicon oxide film on the first silicon oxide film by a film forming process using a CVD method after (h1),
wherein the gate insulating film and the second insulating film each include the first silicon oxide film and the second silicon oxide film.

6. The method of manufacturing a semiconductor device according to claim 1, further comprising:
(j) between (d) and (e), reducing a thickness of the first insulating film and exposing an upper portion of the field plate electrode from the first insulating film; and
(k) between (j) and (e), performing an isotropic etch process on the upper portion of the field plate electrode exposed from the first insulating film.

7. The method of manufacturing a semiconductor device according to claim 6, wherein (d) comprises:
(d1) forming a first conductive film on the first insulating film so as to fill the inside of the trench;
(d2) after (d1), removing the first conductive film formed outside the trench; and
(d3) after (d2), forming the first conductive film left inside the trench as the field plate electrode by retracting the position of the upper surface of the first conductive film inside the trench by an anisotropic etch process.

8. The method of manufacturing a semiconductor device according to claim 7, wherein the field plate electrode is made of a polycrystalline silicon film, and the isotropic etching process in (k) is a chemical dry etching process using a CF₄ gas.

9. The method of manufacturing a semiconductor device according to claim 8, wherein an upper corner of the field plate electrode is chamfered or rounded by the chemical dry etch process.

10. The method of manufacturing a semiconductor device according to claim 7, wherein the first insulating film is made of a silicon-oxide film, and (j) and (e) are each performed by an isotropic etch process using a hydrofluoric acid-containing solution.

11. A semiconductor device comprising:
a semiconductor substrate of a first conductivity type having an upper surface and a lower surface;
a trench formed in the semiconductor substrate so as to reach a predetermined depth from the upper surface of the semiconductor substrate toward the lower surface of the semiconductor substrate;
a field plate electrode formed inside the trench;
a gate electrode formed above the field plate electrode inside the trench; and
an insulating film formed inside the trench so as to be located between each of the semiconductor substrate, the field plate electrode, and the gate electrode,
wherein a corner of an upper portion of the field plate electrode is chamfered or rounded,
wherein a part of the gate electrode is formed also between the field plate electrode and the semiconductor substrate as an embedded portion, and
wherein a thickness of the insulating film formed between the embedded portion and the field plate electrode is thickest between the deepest portion of the embedded portion and the field plate electrode.

12. The semiconductor device according to claim 11, wherein a thickness of the insulating film formed between the embedded portion and the semiconductor substrate is thickest between the deepest portion of the embedded portion and the semiconductor substrate.

13. The semiconductor device according to claim 12, wherein the insulating film is a silicon-oxide film.

14. The semiconductor device according to claim 12, further comprising:
a body region of a second conductivity type opposite to the first conductivity type formed in the semiconductor substrate so that a depth from the upper surface of the semiconductor substrate is shallower than a depth of the trench;
a source region of the first conductivity type formed in the body region; and
a drain region of the first conductivity type formed in the semiconductor substrate so as to reach a predetermined depth from the lower surface of the semiconductor substrate toward the upper surface of the semiconductor substrate,
wherein a gate potential is supplied to the gate electrode,
wherein a source potential is supplied to the field plate electrode, the body region, and the source region, and
wherein a drain potential is supplied to the semiconductor substrate and the drain region.
